(19) United States
(12) Patent Application Publication
(10) Pub. No.: US 2015/0278681 A1
(43) Pub. Date: Oct. 1, 2015

(54) MEMORY CONTROLLED CIRCUIT SYSTEM AND APPARATUS

(71) Applicant: Boise State University, Boise, ID (US)

(72) Inventor: VISHAL SAXENA, Boise, ID (US)

(21) Appl. No.: 14/538,469

(22) Filed: Nov. 11, 2014

Related U.S. Application Data
(60) Provisional application No. 61/973,754, filed on Apr. 1, 2014.

(51) Int. Cl. G06N 3/063; G06N 3/08; G11C 7/22; G11C 27/02; G11C 11/24

(52) U.S. Cl. CPC G06N 3/0635; G11C 27/024; G11C 11/24; G11C 7/22; G06N 3/08

(57) ABSTRACT

A memory controlled circuit includes a configurable circuit element electrically coupled to a first terminal and to a second terminal. The circuit may further include a transconductor. A first input of the transconductor may be electrically coupled to the first terminal and a second input of the transconductor may be electrically coupled to the second terminal. The circuit may also include a switch coupled to an output of the transconductor. The circuit may include a dynamic analog memory electrically coupled to the configurable circuit element and to the switch.

### RELATED APPLICATIONS

This application, under 35 U.S.C. §119, claims the benefit of U.S. Provisional Patent Application Ser. No. 61/973,754 filed on Apr. 1, 2014, and entitled “DYNAMIC SYNAPSE CIRCUITS,” which is hereby incorporated by reference herein.

### FIELD OF THE DISCLOSURE

The present disclosure generally relates to a memory controlled circuit and more particularly to a synapse-type memory controlled circuit.

### BACKGROUND

Computing technology continues to advance by steadily scaling transistor size and by adding more complexity to processing devices while also lowering power consumption in the processing devices. However, as computing technology becomes smaller and more complex, it is increasingly difficult to maintain the current scaling rates. Traditional computer architectures, such as the von-Neumann architecture, require a large number of interconnects and other components. The von-Neumann architecture may be insufficient to keep up with the rapid pace of scaling associated with newer computing devices. For example, current difficulties associated with traditional computer architectures include device variability and interconnect bottlenecks. These difficulties become more pronounced as computing devices become smaller. In order to ensure continued advances in computing technology, new computer architectures are needed to overcome the scaling difficulties associated with traditional computer architectures.

### SUMMARY

Disclosed is a memory controlled circuit that may at least partially emulate a synapse of a biological brain. The memory controlled circuit includes a transistor or another type of configurable circuit to generate a variable resistance or a variable capacitance between two terminals. The transistor or other type of configurable circuit may be controlled by a state of the memory controlled circuit. The memory controlled circuit may further include a capacitor or other dynamic analog memory to store the state. A transconductor may sense a voltage difference between the two terminals and may change the state of the memory controlled circuit based on the voltage difference. A switch, using an asynchronous strobe or a system clock as an input, may assist the transconductor in changing the state of the memory controlled circuit.

In an embodiment, a memory controlled circuit includes a configurable circuit element electrically coupled to a first terminal and to a second terminal. The circuit further includes a transconductor. A first input of the transconductor is electrically coupled to the first terminal and a second input of the transconductor is electrically coupled to the second terminal. The circuit also includes a switch coupled to an output of the transconductor. The circuit includes a dynamic analog memory electrically coupled to the configurable circuit element and to the switch.

In an embodiment, the configurable circuit comprises a transistor configured to operate in a linear region mode or a near-linear region mode. The transistor may be a zero threshold voltage transistor. The transistor may be an N-channel field effect transistor (FET), a P-channel FET, an NPN bipolar junction transistor (BJT), a PNP BJT, or a junction gate field-effect transistor (JFET).

In an embodiment, the configurable circuit includes a variable capacitor. The variable capacitor may include a three-terminal varactor.

In an embodiment, the dynamic analog memory includes a capacitor electrically coupled to a control input of the configurable circuit element and electrically coupled to a common voltage. The capacitor may have a capacitance of between about 100 femtofarads and five picofarads.

In an embodiment, the memory controlled circuit further includes a bi-stable latch coupled to the configurable circuit element. The memory controlled circuit may also include a strobe signal source coupled to the switch. The strobe signal source may include a system clock.

In an embodiment, the strobe signal source includes an event detector circuit. A first input of the event detector circuit may be electrically coupled to the first terminal and a second input of the event detector circuit may be electrically coupled to the second terminal. An output of event detector circuit may be electrically coupled to the switch.

In an embodiment, the event detector circuit includes an absolute difference circuit configured to generate a signal indicating a magnitude of a voltage difference between the first terminal and the second terminal. The event detector circuit may further include an asynchronous comparator configured to set a strobe signal to a logical high in response to the magnitude of the voltage difference exceeding a threshold.

In an embodiment, the event detector circuit includes a first asynchronous comparator configured to set a strobe signal to a logical high in response to a voltage difference between the first terminal and the second terminal exceeding a first threshold. The event detector may further include a second asynchronous comparator configured to set the strobe signal to a logical high in response to the voltage difference between the first terminal and the second terminal being lower than a second threshold.

In an embodiment, a method of controlling an electrical property of a circuit includes sensing a voltage difference between a first terminal and a second terminal of a memory controlled circuit. The method further includes changing a value of a dynamic analog memory based on the voltage difference. The method also includes changing an electrical property of a configurable circuit element positioned between the first terminal and the second terminal based on the value of the dynamic analog memory.

In an embodiment, changing the value of the dynamic analog memory includes increasing or decreasing the value of the dynamic analog memory based on an integration operation performed on the sensed voltage difference over time. Changing the electrical property of the configurable circuit element may include increasing or decreasing a resistance of the configurable circuit element or increasing or decreasing a capacitance of the configurable circuit element.

In an embodiment, a system of memory controlled circuits includes at least one input neuron device. The system further includes at least one output neuron device. The system also includes at least one memory controlled circuit. The at least one input neuron device is coupled to the at least one output neuron device via the at least one memory controlled circuit. The memory controlled circuit includes a configurable circuit element electrically coupled to a first terminal and to a second terminal. The memory controlled circuit further includes a transconductor. A first input of the transconductor is electrically coupled to the first terminal and a second input of the transconductor is electrically coupled to the second terminal. The memory controlled circuit element also includes a switch coupled to an output of the transconductor. The memory controlled circuit element includes a dynamic analog memory electrically coupled to the configurable circuit element and to the switch. In an embodiment, the at least one memory controlled circuit enables bi-directional communication between the at least one input neuron device and the at least one output neuron device.

In an embodiment, the memory controlled circuit is configured to control an electrical property of the configurable circuit element based on a voltage difference between a first voltage spike generated by the at least one input neuron device at the first terminal and a second voltage spike generated by the at least one output neuron device at the second terminal. The first voltage spike may be generated in response to the second voltage spike or the second voltage spike may be generated in response to the first voltage spike. The electrical property of the configurable circuit element may be changed when a period of time between the first voltage spike and the second voltage spike is less than a threshold.

In an embodiment, the system further includes at least one analog-to-digital converter coupled to the dynamic analog memory, the analog-to-digital converter enabling a controller to perform a read operation corresponding to the dynamic analog memory. The system may also include at least one digital-to-analog converter coupled to the at least one memory controlled circuit, the digital-to-analog converter enabling a controller to perform a write or refresh operation corresponding to the dynamic analog memory. In an embodiment, the system further includes a memory array configured to store a value corresponding to the dynamic analog memory.

In an embodiment, the system includes a plurality of input neuron devices, the plurality of input neuron devices including the at least one input neuron device. The system may further include a plurality of output neuron devices, the plurality of output neuron devices including the at least one output neuron device. The system may also include a plurality of memory controlled circuits, each of the plurality of memory controlled circuits including the at least one memory controlled circuit. Each input neuron device of the plurality of input neuron devices may be electrically coupled to each output neuron device of the plurality of output neuron devices via memory controlled circuits. The plurality of memory controlled circuits may be organized in a cross-point array configuration. The cross point array configuration may be a dense neural network layer or a machine learning data structure.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives, both structural and operational, falling within the spirit and scope of the disclosure as defined by the appended claims.

### BRIEF DESCRIPTION OF THE DRAWINGS

FIG. 1A illustrates a conceptual block diagram for an embodiment of a synapse-type memory controlled circuit;

FIG. 1B illustrates a circuit implementation of an embodiment of a synapse-type memory controlled circuit;

FIG. 2A illustrates a current-voltage hysteresis curve for a simulated embodiment of a synapse-type memory controlled circuit;

FIG. 2B illustrates a state trajectory for the simulated embodiment of the synapse-type memory controlled circuit when swept with a sine-wave input at 1 MHz frequency;

FIG. 3 illustrates a pulsed characterization response of the simulated embodiment of the synapse-type memory controlled circuit showing monotonic incremental state control;

FIG. 4 illustrates an embodiment of a synapse-type memory controlled circuit with asynchronous weight update, compatible with spike timing-dependent plasticity (STDP) learning mechanisms.

FIGS. 5A-5B illustrate embodiments of a synapse-type memory controlled circuit with asynchronous weight update using an embodiment of an event detector, compatible with STDP learning mechanisms.

FIGS. 6A-6B illustrate an example of an STDP learning mechanism in a bio-inspired synapse-type memory controlled circuit.

FIGS. 7A-7B illustrate an example of STDP-type synaptic weight updates that depend on the relative timing of the pre- and post-synaptic action potentials.

FIG. 8A illustrates a conceptual block diagram of an embodiment of a synapse-type memory controlled circuit.

FIG. 8B illustrates a circuit implementation of an embodiment of a synapse-type memory controlled circuit.

FIGS. 9A-9B illustrate embodiments of a synapse-type memory controlled circuit compatible with digital spikes.

FIG. 10A illustrates characteristic timing and waveforms of an embodiment of a synapse-type memory controlled circuit using digital spikes.

FIG. 10B illustrates an STDP learning function exhibited by an embodiment of a synapse-type memory controlled circuit using digital spikes.

FIG. 11 illustrates an embodiment of a synapse-type memory controlled circuit with an exponential decay circuit.

FIG. 12 illustrates an embodiment of a synapse-type memory controlled circuit with an exponential decay circuit.

FIGS. 13A-13B illustrate embodiments of a bi-stable synapse-type memory controlled circuit.

FIG. 14 illustrates an embodiment of a system 800 memory controlled circuits with a store and refresh scheme using an ADC/DAC combination.

### DETAILED DESCRIPTION

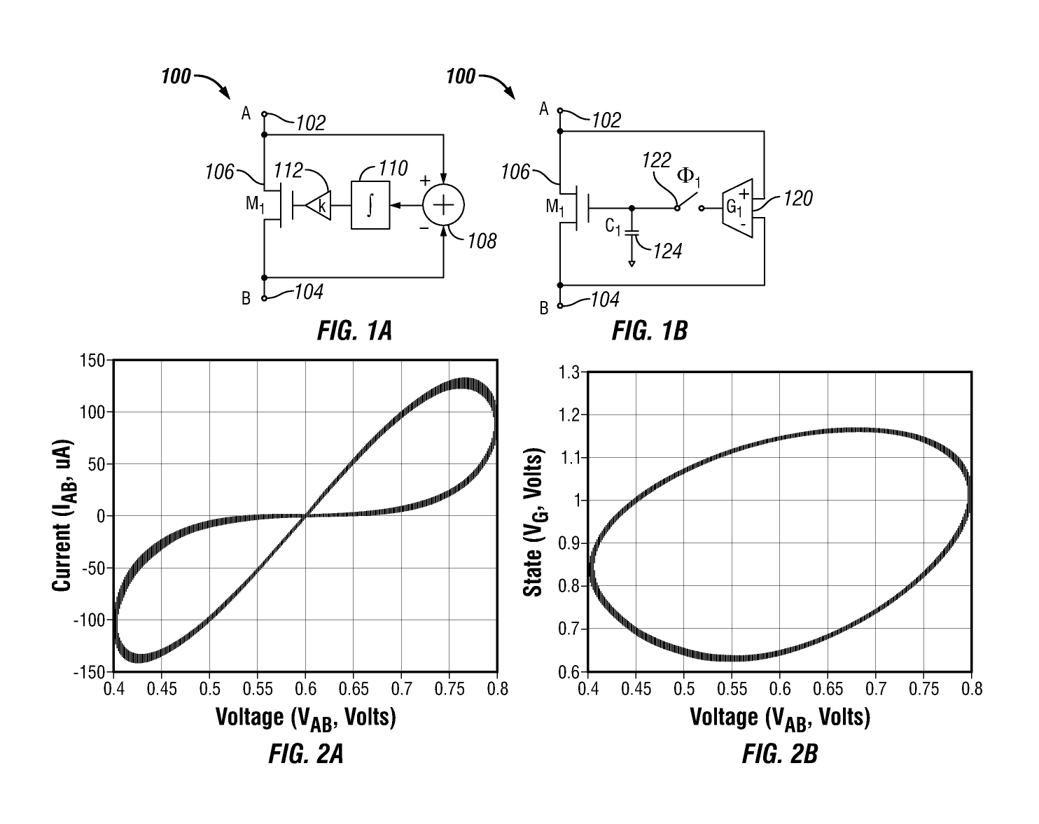

Referring to FIG. 1A, a conceptual block diagram of an embodiment of a synapse-type memory controlled circuit 100 is depicted. The memory controlled circuit 100 includes a first terminal 102, a second terminal 104, and a configurable circuit element 106 coupled to the first terminal 102 and to the second terminal 104. The functionality of the memory controlled circuit 100 is depicted conceptually by a voltage difference sensing phase 108, an integration phase 110, and a gain control phase 112, as described herein.

The configurable circuit element 106 may include a transistor. For example, as shown in FIG. 1A, a transistor M1 may be coupled between the first terminal 102 and the second terminal 104. A drain of the transistor M1 may be coupled to the first terminal and a source of the transistor M1 may be coupled to the second terminal 104. Alternatively, the source of the transistor M1 may be coupled to the first terminal 102 and the drain of the transistor M1 may be coupled to the second terminal 104. The transistor M1 may be configured to operate in a linear (e.g., triode) or near-linear operating mode. For example, the transistor M1 may be a zero threshold voltage transistor to enable the transistor M1 to operate in a linear or near linear mode for large signal excursions. Operating the transistor M1 in a linear or near linear mode enables the memory controlled circuit 100 to exhibit variable resistance between the first terminal 102 and the second terminal 104, as controlled by a gate voltage of the transistor M1.

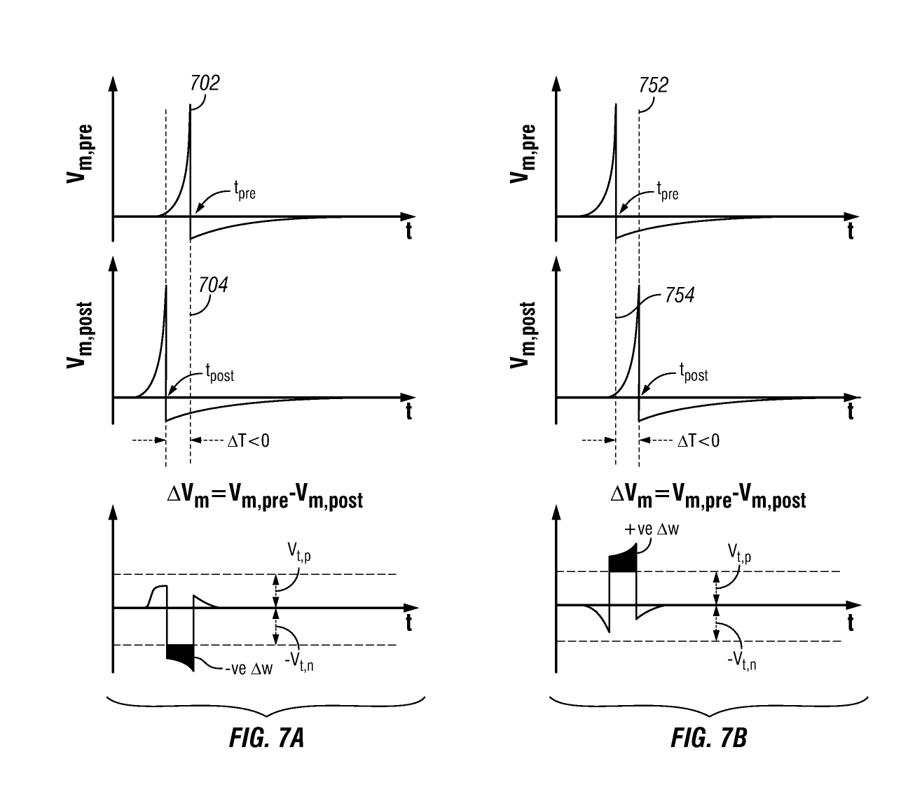

Although FIG. 1A depicts the configurable circuit element 106 as a type of field effect transistor (FET), in other embodiments, the configurable circuit element 106 may be any type of three-terminal switch. For example, the configurable circuit element 106 may be an N-channel field effect transistor (FET), a P-channel FET, an NPN bipolar junction transistor (BJT), a PNP BJT, a junction gate field-effect transistor (JFET), or another type of three-terminal switch. In one embodiment the three-terminal switch includes a variable capacitor, as described further with reference to FIGS. 7A and 7B.

During operation, a voltage difference V_{AB} between the first terminal 102 and the second terminal 104 may be sensed as represented by the voltage difference sensing phase 108. During the integration phase 110, the voltage difference may be integrated over time. To illustrate, a value (or a “state” in terms of a synapse) stored at a dynamic analog memory may be increased or decreased based on an integration operation performed on the voltage difference V_{AB} over time. For example, the dynamic analog memory may include a capacitor, and the value (or state) may include a charge stored at the capacitor, as described further with reference to FIG. 1B. The charge may be increased when the voltage difference V_{AB} exceeds a positive threshold and decreased when the voltage difference falls below a negative threshold. A particular embodiment of the implementation of the integration phase 110 and the dynamic analog memory are further described with reference to FIG. 1B.

At the gain control phase 112, the value of the dynamic analog memory may be used to configure the configurable circuit element 106. For example, an electrical property of the configurable circuit element 106 may be changed based on the value. To illustrate, in embodiments where the configurable circuit element 106 includes the transistor M1, the value of the dynamic analog memory may be used to generate a gate voltage at the transistor M1. A resistance between the drain and the source of the transistor M1 (and also between the first terminal 102 and the second terminal 104) may be changed based on changes to the gate voltage. For example, depending on the particular implementation, an increase in the gate voltage may result in a decrease in resistance between the drain and the source and a decrease in the gate voltage may result in an increase in resistance between the drain and the source.

The synapse-type memory controlled circuit 100 may provide a floating variable resistance between the first terminal 102 and the second terminal 104 controlled by a memory element (e.g., the dynamic analog memory). If a positive voltage is applied across the memory controlled circuit (if a voltage at the first terminal 102 is greater than a voltage at the second terminal 104) then the gate voltage is increased. The increase in the gate voltage may result in a decrease of resistance between the first terminal 102 and the second terminal 104. Hence, the synapse-type memory controlled circuit 100 is “programmed.” Similarly, if a negative voltage is applied across the memory controlled circuit (if a voltage at the first terminal 102 is less than a voltage at the second terminal 104) then the gate voltage is decreased. The decrease in gate voltage may result in an increase of resistance between the first terminal 102 and the second terminal 104. Hence the synapse-type memory controlled circuit 100 is “erased.” As such, the synapse-type memory controlled circuit 100 may exhibit the dynamic functionality of a fourth fundamental circuit element (i.e., in addition to a resistor, a capacitor, and an inductor) called a “memristor”. The synapse-type memory controlled circuit 100 may further substantially mimic a wide variety of biological synapses found in animal brain and neuro-muscular system, and may be used in conjunction with biologically compatible plasticity learning rules including spike-timing dependent plasticity (STDP), anti-STDP, and Hebbian-type learning.

Referring to FIG. 1B, a circuit implementation of an embodiment of the synapse-type memory controlled circuit 100 is depicted. The memory controlled circuit 100 may include a transconductor 120, a switch 122, and a dynamic analog memory, such as a capacitor 124. The transconductor 120, the switch 122, and the capacitor 124 may realize the functionality described with reference to FIG. 1A. For example, the transconductor 120, the switch 122, and the capacitor 124 may each perform portions of operations corresponding to the voltage difference sensing phase 108, the integration control phase 110, and the gain control phase 112, of FIG. 1A, as described herein.

In the embodiment depicted in FIG. 1B, the transconductor 120 may be configured to sense a voltage difference between the first terminal 102 and the second terminal 104 and to generate a current based on the voltage difference. For example, the transconductor 120 may include a circuit that implements a voltage controlled current source (VCCS). The VCCS may include an operational transconductor amplifier (OTA), a differential amplifier, a single-ended transconductor, or another type of transconductor circuit. The transconductor 120 may be further configured to transmit the generated current to the switch 122.

The switch 122 may be coupled to an output of the transconductor 120 and to the capacitor 124. The position of the switch 122 within the synapse-type memory controlled circuit 100 may enable the switch 122 to electrically connect the transconductor 120 to the capacitor 124 and to electrically disconnect the transconductor 120 from the capacitor 124 based on an external strobe Φ1 received at the switch 122. For example, when the external strobe Φ1 is a logical high, the switch 122 may be configured to electrically couple an output of the transconductor 120 to the capacitor 124. When the external strobe Φ1 is a logical low, the switch 122 may be configured to electrically uncouple the output of the transconductor 120 from the dynamic analog memory 124.

The capacitor 124 may be coupled to an output of the switch 122 and to an input of the configurable circuit element 106. The input of the configurable circuit element 106 may be a control input of the configurable circuit element 106. For example, in embodiments where the configurable circuit element 106 includes the transistor M1, the control input may correspond to a gate of the transistor M1. The capacitor may also be coupled to a common voltage (e.g., a ground voltage) to enable the capacitor to store a charge at the input of the configurable circuit element 106. The charge may be used to store a value (or state) of the synapse-type memory controlled circuit 100. The value may control an electrical property of the configurable circuit element 106. For example, in the embodiment shown in FIG. 1B, the value may control a resistance of the configurable circuit element 106.

The capacitor 124 may include any type of capacitive element. For example, the capacitor 124 may include an N-channel capacitor, a P-channel capacitor, a MOSCAP poly-poly capacitor, a reversed biased diode, or another type of capacitive element. In one embodiment, a capacitance value of the capacitor is between about 100 femtofarads to five picofarads when implemented on a complementary metallic oxide semiconductor (CMOS) chip. Although FIG. 1B depicts the dynamic analog memory as being the capacitor 124, in other embodiments, the dynamic analog memory may include other types of memory usable to store an analog value.

During operation, the transconductor 120 may sense a voltage difference between the first terminal 102 and the second terminal 104. Based on the voltage difference, the transconductor 120 may generate a current at an output of the transconductor 120. The switch 122 may receive the generated current.

As described above, the switch 122 may be controlled by the external strobe Φ1. When the strobe Φ1 is a logical high, the switch 122 may electrically couple the output of the transconductor 120 to the capacitor 124, thereby enabling the current generated by the transconductor 120 to be applied to the capacitor 124. The generated current may change a charge at the capacitor 124. For example, the value of a charge held at the capacitor 124 may be increased or decreased based on the current generated by the transconductor 120. Applying the generated current to the capacitor 124, and thereby generating a voltage at the capacitor 124, may have the effect of integrating the voltage difference sensed by the transconductor 120 over time with an effective gain k. Hence, the current integration phase 108 described with reference to FIG. 1A may be performed.

When the external strobe Φ1 is a logical low, the capacitor 124 may be electrically disconnected from the transconductor 120 and may hold a value (or state) as a stored charge, thus exhibiting the characteristics of the dynamic analog memory.

For synchronous operations, the external strobe Φ1 may be provided by a system clock. This configuration may be useful in machine learning applications that synchronously process data. Alternatively, in a bio-inspired spiking neural network (SNN), neurons may fire asynchronously based on sparse spiking input patterns. In an asynchronous application the strobe Φ1 may be generated using spiking inputs (or “action potentials” in terms of a synapse) applied to the synapse-type memory controlled circuit as described further with reference to FIG. 4.

The value of the dynamic analog memory (e.g., the value of the charge stored at the capacitor 124) may control the configurable circuit element 106. For example, in embodiments where the configurable circuit element 106 is the transistor M1, as illustrated by FIGS. 1A and 1B, a voltage stored at the capacitor 124 may control a gate voltage of the transistor M1. When the transistor M1 is operated in a linear or near-linear operating mode, the transistor M1 may perform the function of a memory controlled variable resistor between the first terminal 102 and the second terminal 104. For example, the drain-source resistance of the transistor M1 may be altered by updating the gate voltage in response to voltage pulses applied across the first terminal 102 and the second terminal 104. If square pulses are used, the incremental update in the gate voltage may be approximately given by

$$Δ {V}_{G} = \frac{{G}_{1}}{{C}_{1}} {V}_{Pulse} Δ T$$

where G1, C1, Vpulse and ΔT are the transconductance of the transconductor 120, the capacitance of the capacitor 124, the pulse height, and the pulse width, respectively. If the transistor M1 is in deep triode (e.g., within the linear operating mode), the current flowing through the synapse-type memory controlled circuit may be approximated by

$$I \approx KP \frac{W}{L} ( {V}_{GS} - {V}_{THN} ) {V}_{AB}$$

where V_{GS} and V_{THN} are the gate-to-source and threshold voltages, KP is the transconductance parameter, W is the width and L is the length of the gate of the transistor M1, and V_{AB} is the voltage difference between the first terminal 102 and the second terminal 104. This results in a resistance between the first terminal 102 and the second terminal 104 that may be approximated by

$$R \approx \frac{1}{KP \frac{W}{L} ( {V}_{GS} - {V}_{THN} )}$$

If the source of the transistor M1 is pinned at a common-mode voltage VCM, then the conductance G (or the “weight” W in terms of synapses) between the first terminal 102 and the second terminal 104 may be approximated by

$$W \approx KP \frac{W}{L} ( {V}_{G} - {V}_{CM} - {V}_{THN} )$$

which shows a direct relation between the state VG and the synaptic weight W. Although, the transistor M1 is described with reference to FIGS. 1A and 1B as being in a linear operating mode, as CMOS technology scales, the saturation resistance for FET transistors may be lowered. Thus, the synapse-type memory controlled circuit 100 may exhibit the above described resistance even when the transistor M1 is in moderate saturation.

The synapse-type memory controlled circuit 100 of FIGS. 1A and 1B realizes a two-terminal variable resistor, with incremental memory in a feedback loop, whose resistance is controlled by external electrical stimulus applied across the two terminals. The resistance of the synapse-type memory controlled circuit 100 can be altered by applying direct current (DC) or pulsed voltage or current across its terminals. The analog memory element (e.g., the capacitor 124) stores the state unless changed by application of an external voltage or current, greater than a threshold. The synapse-type memory controlled circuit 100 may also act as a compact emulator for a fourth fundamental circuit element (i.e., in addition to a resistor, a capacitor, and an inductor) called a “memristor.” The synapse-type memory controlled circuit 100 may have application in resistive memory devices (ReRAMs), and may substantially mimic spike-based learning and weight storage functionality of biological synapses found in an animal brain. The synapse-type memory controlled circuit 100 can be designed and fabricated using standard commercial CMOS technologies and may be used for realizing chip-scale circuits for implementing Machine learning algorithms and neurobiology-inspired electronic circuits that may emulate cognitive computing functionality of a biological brain.

While the transconductor 120, the switch 122, and the capacitor 124 may together perform operations corresponding to the voltage difference sensing phase 108, the integration phase 110, and the gain control phase 112 of FIG. 1A, it should be understood that a single component of FIG. 1B does not necessarily map to a single phase of FIG. 1A. For example, a combination of multiple components (e.g., the capacitor 124 and the switch 122) may perform at least a portion of a single phase (e.g., the current integration phase 110).

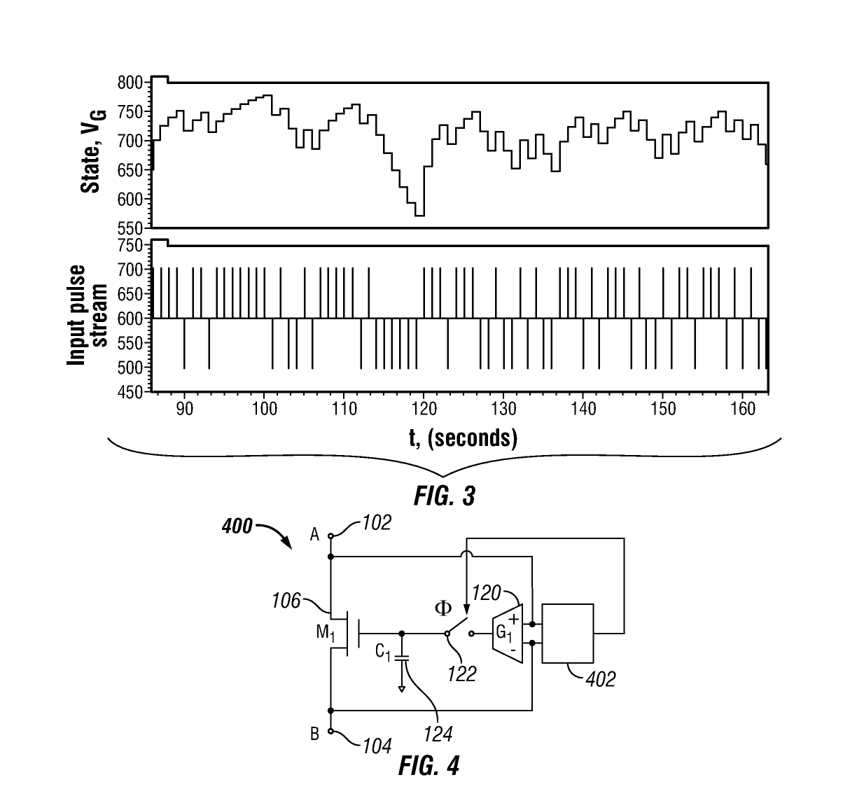

FIGS. 2A, 2B, and 3 illustrate various simulation results of an embodiment of a synapse-type memory controlled circuit. The synapse-type memory controlled circuit of FIGS. 2A, 2B, and 3 may correspond to the synapse-type memory controlled circuit 100 of FIGS. 1A and 1B. For example, the synapse-type memory controlled circuit 100 of FIGS. 1A and 1B may exhibit the characteristics described with reference to FIGS. 2A, 2B, and 3.

Referring to FIG. 2A, a current-voltage hysteresis curve for a simulated embodiment of a synapse-type memory controlled circuit is depicted. For simulation purposes, the synapse-type memory controlled circuit was designed using a 130 nm CMOS process with a supply voltage of 1.2V, and simulated using foundry device models in Cadence Spectre. The synapse-type memory controlled circuit was swept with a sinusoidal input having a frequency of 1 MHz, an amplitude of 200 mV, and a common-mode DC offset (VCM) of 600 mV, while the strobe Φ1 was held at a logical high (1.2 V). As shown by the current-voltage hysteresis curve, the circuit characteristics of the synapse-type memory controlled circuit exhibit a pinched hysteresis curve typical of a memristor.

Referring to FIG. 2B, a state trajectory for the simulated embodiment of the synapse-type memory controlled circuit when swept with a sine-wave input at 1 MHz frequency is depicted. This waveform can be understood as successive voltage sweeps being applied to the synapse-type memory controlled circuit, to trace closely spaced analog memory states. As shown in FIG. 2B, the circuit characteristics associated with the synapse-type memory controlled circuit exhibit memristor behavior. For example, FIG. 2 demonstrates that the synapse-type memory controlled circuit can hold analog memory states, which can be precisely controlled by external stimuli. Hence, the simulation corresponding to FIG. 2B further confirms that the synapse-type memory controlled circuit may function as a memristor.

Referring to FIG. 3, a pulsed characterization response of the simulated embodiment of the synapse-type memory controlled circuit showing monotonic incremental state control is depicted. The simulation results depicted in FIG. 3 show that the synapse-type memory controlled circuit exhibits a state retention property. The simulation was performed by applying a pseudorandom sequence with 100 mV pulses (Vpulse=100 mV) applied across the terminals of the synapse-type memory controlled circuit every 5 ns (ΔT=5 ns), where a drain of a transistor (corresponding to the transistor M1 of FIGS. 1A and 1B) is tied to a common-mode voltage of 600 mV (VCM=600 mV) with 1 MHz clock rate. FIG. 3 shows that the gate voltage (or state), V_{G}, is incrementally updated based on a positive or negative pulse input. Since the weight updates of the synapses are monotonic with respect to the applied pulses (or spikes), the synapse-type memory controlled circuit may be used to store analog weights in a machine learning or spiking neural network circuit.

Referring to FIG. 4, an embodiment of a synapse-type memory controlled circuit 400 with asynchronous weight update that is compatible with spike timing-dependent plasticity (STDP) learning mechanisms is depicted. The synapse-type memory controlled circuit 400 may correspond to the synapse-type memory controlled circuit 100 described herein. For example, the synapse-type memory controlled circuit 400 may include a first terminal 102, a second terminal 104, a configurable circuit element 106, a transconductor 120, a switch 122, and a capacitor 124. The synapse-type memory controlled circuit 400 may further include a strobe signal source, such as an event detector circuit 402.

The event detector circuit 402 may be coupled to the first terminal 102 and the second terminal 104. For example, a first input of the event detector circuit 402 may be coupled to the first terminal 102 and a second input of the event detector circuit 402 may be coupled to the second terminal 104. An output of the event detector circuit 402 may be coupled to the switch 122. The event detector circuit 402 may generate the strobe Φ1, and may be configured to provide the strobe Φ1 to the switch 122.

During operation, the event detector circuit 402 may asynchronously monitor a voltage difference between the first terminal 102 and the second terminal 104 and may generate the strobe Φ1 when a particular condition occurs. For example, the strobe Φ1 may have a logical high value when a voltage difference V_{AB} between the first terminal 102 and the second terminal 104 is greater than an upper threshold or is lower than a lower threshold.

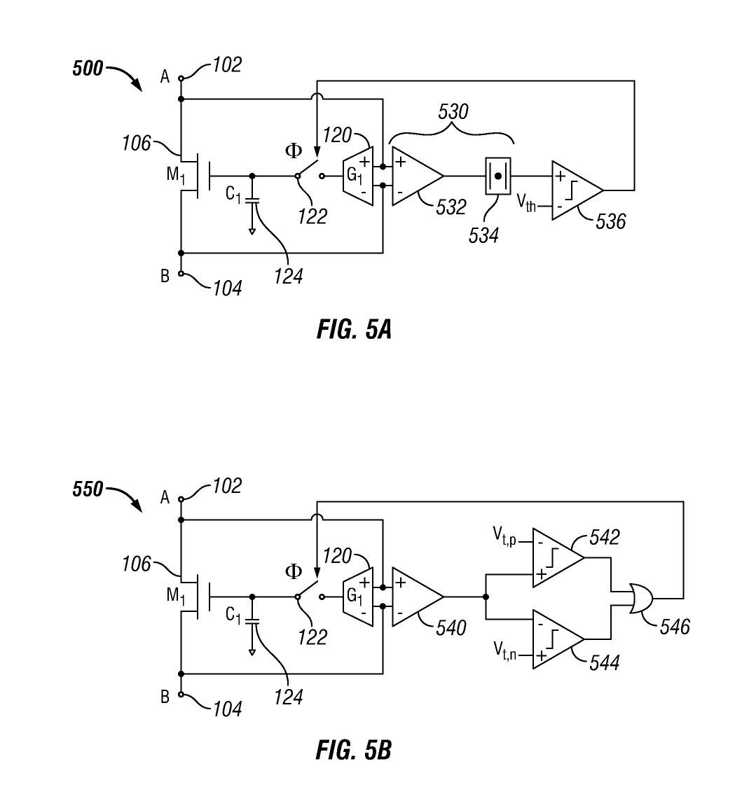

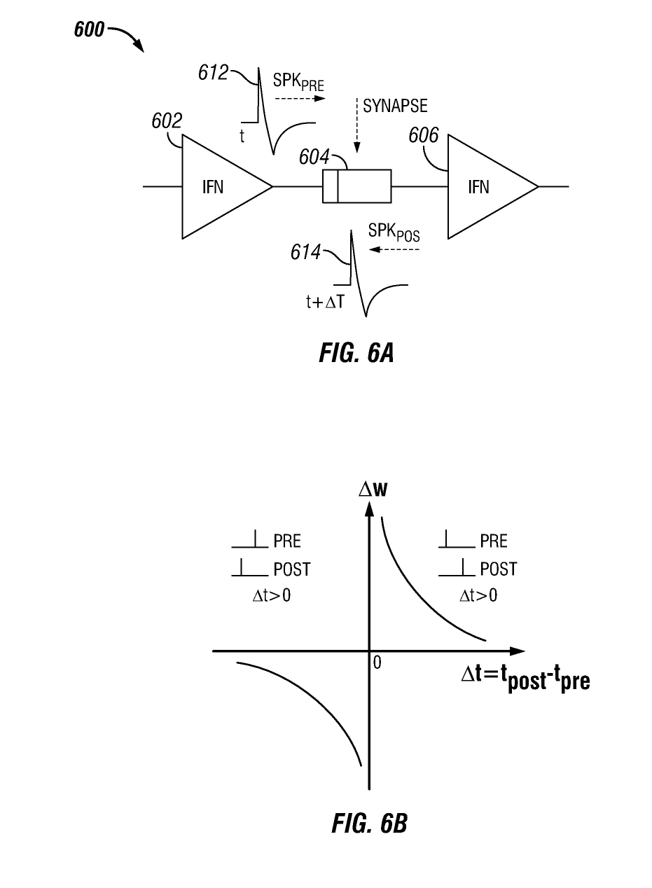

The functioning of the hysteresis comparator 402 may be compatible with one or more spike dependent plasticity (STDP) learning rules observed in biological synapses, as described further with reference to FIGS. 6A, 6B, 7A, and 7B. The upper threshold and the lower threshold may be customized depending on a controlling hysteresis of the event detector 402. Particular embodiments of a synapse-type memory controlled circuit with embodiments of event detectors are described further with reference to FIGS. 5A and 5B. Although, the synapse-type memory controlled circuit 400 is depicted in FIG. 4 as including the event detector 402 as the external strobe source, in other embodiments the synapse-type memory controlled circuit 400 may include a system clock as the external strobe source.

Referring to FIG. 5A, an embodiment of a synapse-type memory controlled circuit with an embodiment of an event detector is depicted and generally designated 500. The circuit 500 may include a first terminal 102, a second terminal 104, a configurable circuit element 106, a transconductor 120, a switch 122, and a capacitor 124. The circuit 500 may also include an absolute difference circuit 530 and an asynchronous comparator 536. In some embodiments, the absolute difference circuit 530 and the asynchronous comparator 536 may correspond to the event detector 402.

The absolute difference circuit 530 may include a comparator 532 and an absolute value circuit 534. A first input of the comparator 532 may be coupled to the first terminal 102 and a second input of the comparator 532 may be coupled to the second terminal 104. An output of the comparator 532 may be coupled to the absolute value circuit 534.

The asynchronous comparator 536 may be coupled to the absolute difference circuit 530 at a first input and to a threshold voltage at a second input. The threshold voltage may be determined based on a particular STDP implementation as may be known to persons of ordinary skill in the art having the benefit of this disclosure. An output of the asynchronous comparator 536 may be coupled to the switch 122.

During operation, the absolute difference circuit 530 and the asynchronous comparator 536 may generate the strobe Φ1 based on a voltage difference between the first terminal 102 and the second terminal 104. For example, the comparator 532 may generate a positive signal or a negative signal related to the voltage difference between the terminals 102, 104. The absolute value circuit 534 may receive the positive or negative signal and may perform an absolute value function to generate a signal that represents a magnitude of the voltage difference. The asynchronous comparator 536 may compare the magnitude of the voltage difference to the threshold voltage. In response to the magnitude of the voltage difference exceeding the threshold voltage, the asynchronous comparator 536 may output a logical high signal as the strobe Φ1.

Referring to FIG. 5B, an embodiment of a synapse-type memory controlled circuit with an embodiment of an event detector is depicted and generally designated 550. The circuit 550 may include a first terminal 102, a second terminal 104, a configurable circuit element 106, a transconductor 120, a switch 122, and a capacitor 124. The circuit 550 may also include a comparator 540, a first asynchronous comparator 542, a second asynchronous comparator 544, and a logical OR circuit 546.

The comparator 540 may correspond to the comparator 532. An output of the comparator 540 may be coupled to a first input of the first asynchronous comparator 542 and a first input of the second asynchronous comparator 544. A first threshold voltage may be provided as an input to the first asynchronous comparator 542 and a second threshold voltage may be provided as an input to the second asynchronous comparator 544. The first threshold voltage may correspond to a positive threshold voltage and the second threshold voltage may correspond to a negative threshold voltage. Outputs of the asynchronous comparators 542, 544 may be coupled to the logical OR circuit 546. The logical OR circuit 546 may be coupled to the switch 122.

During operation, the comparator 540 may generate a positive signal or a negative signal related to the voltage difference between the terminals 102, 104. The first asynchronous comparator 542 may compare the voltage difference to the first threshold voltage. In response to the voltage difference exceeding the first threshold voltage, the first asynchronous comparator 542 may output a logical high signal. Likewise, the second asynchronous comparator 544 may compare the voltage difference to the second threshold voltage. In response to the voltage difference being less than the second threshold voltage, the second asynchronous comparator 544 may output a logical high signal. In response to a logical high signal from either of the asynchronous comparators 542, 544, the logical OR circuit 546 may generate a logical high signal as the strobe Φ1. It should be noted that in the embodiments depicted in FIGS. 5A and 5B, the voltage difference between the terminals 102, 104 may be evaluated using either voltage or current mode differencing.

Referring to FIG. 6A, an example of an STDP learning mechanism in a bio-inspired system 600 is depicted. The system 600 includes a pre-synaptic neuron 602, a synapse-type memory controlled circuit 604, and a post-synaptic neuron 606. The synapse-type memory controlled circuit 604 may correspond to the synapse-type memory controlled circuit 400 of FIG. 4. In particular, the synapse-type memory controlled circuit 604 may include the event detector 402 of FIG. 4, which may be configured to function according to the STDP learning mechanism described herein.

The pre-synaptic neuron 602 may be coupled to a first terminal of the synapse-like memory controlled circuit 604 to enable a first signal (e.g., a first voltage spike 612) to be received by the synapse-like memory controlled circuit 604 from the pre-synaptic neuron 602 at the first terminal. Similarly, the post-synaptic neuron 606 may be coupled to a second terminal of the synapse-like memory controlled circuit 604 to enable a second signal (e.g., a second voltage spike 614) to be received by the synapse-like memory controlled circuit 604 from the post-synaptic neuron 606.

During operation, the first voltage spike 612 may be generated by the pre-synaptic neuron and transmitted to the post-synaptic neuron 606 via the synapse-type memory controlled circuit 604. In response to the first voltage spike 612, the post-synaptic neuron 606 may generate the second voltage spike 614 and transmit the second voltage spike 614 to the pre-synaptic neuron 602 via the synapse-like memory controlled circuit 604. Hence, the synapse-type memory controlled circuit 604 enables bi-directional communication between the pre-synaptic neuron 602 and the post-synaptic neuron 606. The shape of the first voltage spike 612 and the second voltage spike 614 may be determined by a desired implementation of an STDP learning rule. In some embodiments, the second voltage spike 614 is comparable to Ca2+ mediated feedback signaling in biological neurons, which effectively update the efficiency (e.g., the weight) of synaptic receptors that bind with neurotransmitters released from synaptic vesicles of a pre-synaptic membrane.

A weight (e.g., a conductance between the first terminal and the second terminal) of the synapse-type memory controlled circuit 604 may be updated based on the first voltage spike 612 and the second voltage spike 614 as shown in FIG. 6B. For example, an electrical property (e.g., a resistance/conductance) of a configurable circuit element of the synapse-type memory controlled circuit 604 may be changed based on a voltage difference between the first voltage spike 612 and the second voltage spike 614, as described with reference to FIGS. 1A and 1B. In a particular STDP implementation, the weight may be updated based on the relative timing of the first voltage spike 612 and the second voltage spike 614. For example, as depicted in FIG. 6B, when the second voltage spike occurs before the first voltage spike (Δt<0), a weight change Δw may be negative. Further, when the first voltage spike occurs before the second voltage spike (Δt>0), the weight change Δw may be positive. In a particular embodiment, the weight is updated when Δt is within a threshold as described further with reference to FIGS. 7A and 7B.

Referring to FIGS. 7A and 7B, an example of STDP-type synaptic weight updates that depend on the relative timing of pre- and post-synaptic action potentials is depicted. FIG. 7A illustrates a pre-synaptic action potential 702 being received after a post-synaptic action potential 704, and FIG. 7B illustrates a pre-synaptic action potential 752 being received before a post-synaptic action potential 754. The pre-synaptic action potentials 704, 752 may correspond to the first voltage spike 612 of FIG. 6A and the post-synaptic action potentials 704, 754 may correspond to the second voltage spike 614 of FIG. 6.

Referring to FIG. 7A, the relative timing of the pre- and post-synaptic action potentials 702, 704 is converted to a potential difference ΔVm dropped across the synapse-type memory controlled circuit. When ΔVm exceeds a negative threshold, a weight of the synapse-type memory controlled circuit is decremented by an amount equal to Δw. If a time period between the pre-synaptic action potential 702 and the post-synaptic action potential 704 is too long, then ΔVm may not exceed the negative threshold and the weight will not be updated.

Referring to FIG. 7B, the relative timing of the pre- and post-synaptic action potentials 752, 754 is again converted to a potential difference ΔVm dropped across the synapse-type memory controlled circuit. When ΔVm exceeds a positive threshold a weight of the synapse-type memory controlled circuit is incremented by an amount equal to Δw. As in FIG. 7A, if a time period between the pre-synaptic action potential 752 and the post-synaptic action potential 754 is too long, then ΔVm may not exceed the positive threshold and the weight will not be updated.

The STDP functionality described with reference to FIGS. 6A, 6B, 7A, and 7B may be performed by the synapse-type memory controlled circuit 400 of FIG. 4. Further, the synapse-type memory controlled circuit 400 may be configurable to implement variants of STDP, which may be developed by the Computational Neuroscience community as will be apparent to persons of ordinary skill in the relevant art having the benefit of this disclosure.

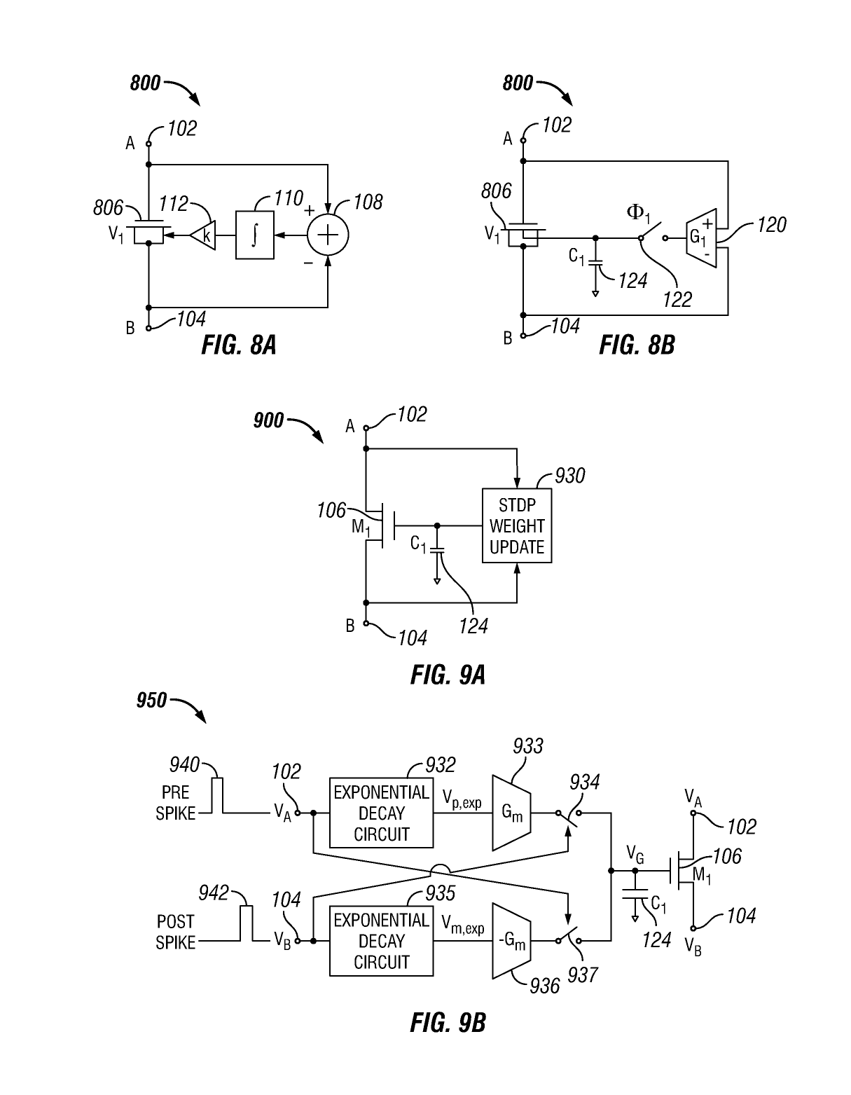

Referring to FIG. 8A, a conceptual block diagram for an embodiment of a synapse-type memory controlled circuit 800 is depicted. The memory controlled circuit 800 may include a first terminal 102 and a second terminal 104. Further, the functionality of the memory controlled circuit 800 may be depicted conceptually by a voltage difference sensing phase 108, an integration phase 110, and a gain control phase 112. The synapse-type memory controlled circuit 800 may include a variable capacitor 806 coupled between the first input 102 and the second input 104. The conceptual operation of the synapse-type memory controlled circuit 800 may be similar to the conceptual operation of the synapse-type memory controlled circuit 100 described herein with the exception that a capacitance (instead of a resistance) between the first terminal 102 and the second terminal 104 may be controlled based on the voltage difference sensing phase 108, the integration phase 110, and the gain control phase 112.

Referring to FIG. 8B, a circuit implementation of an embodiment of the synapse-type memory controlled circuit 800 is depicted. The memory controlled circuit 800 may include the transconductor 120, the switch 122, and the dynamic analog memory, such as the capacitor 124. The synapse-type memory controlled circuit 800 may further include the variable capacitor 806 of FIG. 8A. The variable capacitor 806 may be a 3-terminal varactor (V₁), implemented using a MOS capacitor in accumulation or inversion mode. For example, the variable capacitor 806 may be implemented in CMOS technology, with a body or a source/drain of a transistor used as a controller.

The synapse-type memory controlled circuit 800 may operate in a similar manner as the synapse-type memory controlled circuit 100 described herein. For example, the transconductor 120 may sense a voltage difference between the first terminal 102 and the second terminal 104. Based on the voltage difference, the transconductor 120 may generate a current at an output of the transconductor 120. The switch 122 may receive the generated current. When a strobe Φ1 is a logical high, the switch 122 may electrically couple the output of the transconductor 120 to the capacitor 124, thereby enabling the current generated by the transconductor 120 to be applied to the capacitor 124. The generated current may change a charge at the capacitor 124. When the strobe Φ1 is a logical low, the capacitor 124 may be electrically disconnected from the transconductor 120 and may hold a value (or state) as a stored charge, thus exhibiting the characteristics of the dynamic analog memory. The value of the dynamic analog memory (e.g., the value of the charge stored at the capacitor 124) may control the variable capacitor 806. For example, a voltage stored at the capacitor 124 may be used to increase or decrease a capacitance of the variable capacitor 806.

The synapse-type memory controlled circuit 800 of FIGS. 8A and 8B may extend the memristor concept to a memcapacitor. The memcapacitor may be used as a capacitive synapse-type memory controlled circuit in a spiking neural network. When used in machine learning and neural network circuits, a capacitive synapse-type memory controlled circuit may result lower power consumption as compared to resistive synapse-type memory controlled circuits.

To realize large-scale neural inspired computing on silicon integrated circuits, the synaptic spikes described herein may include digital pulses instead of the analog-like action potentials with exponential tails as depicted in FIGS. 7A and 7B. Referring to FIG. 9A, an embodiment of a synapse-type memory controlled circuit compatible with digital spikes is depicted and generally designated 900. Like the embodiment described with reference to FIG. 1B, the synapse-type memory controlled circuit 900 may include a first terminal 102, a second terminal 104, a configurable circuit element 106, and a capacitor 124. The circuit 500 may also include an STDP weight update circuit 930.

The STDP weight update circuit 930 may sense digital pulses occurring at the terminals 102, 104, and may convert their relative timing into a change in a weight of the synapse-like memory controlled circuit 900. For example, the STDP weight update circuit 930 may change a voltage across the capacitor 124 based on the relative timing.

Referring to FIG. 9B, an embodiment of a synapse-type memory controlled circuit compatible with digital spikes is depicted and generally designated 950. The synapse-type memory controlled circuit 950 may include a first exponential decay circuit 932, a first transconductor 933, a first switch 934, a second exponential decay circuit 935, a second transconductor 936, and a second switch 937. The exponential decay circuits 932, 935, the transconductors 933, 936, and the switches 934, 937 may correspond to the STDP weight update circuit 930.

The first exponential decay circuit 932 may be electrically coupled between the first terminal 102 and the first transconductor 933. An input of the first transconductor 933 may be coupled to the first exponential decay circuit 932 and an output of the first transconductor 933 may be coupled to the first switch 934. Likewise, the second exponential decay circuit 935 may be coupled between the second terminal 104 and the second transconductor 936. An input of the second transconductor 936 may be coupled to the second exponential decay circuit 935 and an output of the second transconductor 936 may be coupled to the second switch 937. The first switch 934 may be controlled by a voltage at the second terminal 104 and the second switch 937 may be controlled by a voltage at the first terminal 102. For example, a digital voltage pulse at the second terminal 104 may cause the first switch 934 to electrically couple an output of the first transconductor 933 to the capacitor 124 and the configurable circuit element 106. Similarly, a digital voltage pulse at the first terminal 102 may cause the second switch 937 to electrically couple an output of the second transconductor 936 to the capacitor 124 and the configurable circuit element 106.

During operation, a first digital pulse 940 (e.g., corresponding to a pre-synaptic spike) may be received at the first terminal 102. The first digital pulse may be shortly followed by a second digital pulse 942 (e.g., corresponding to a post-synaptic spike). In response to the first digital pulse 940, the first exponential decay circuit 932 may generate an exponentially decaying response voltage that gradually decays over a period of time. The first transconductor 933 may generate a current based on the exponentially decaying response voltage. When the second digital pulse 942 is received at the second terminal 104, the first switch 934 may connect the generated current to the capacitor 124, thereby changing a voltage level at the capacitor 124. In an embodiment, the first transconductor 933 generates a positive current that increases a voltage across the capacitor 124, thereby updating a weight of the synapse-type memory controlled circuit 950.

In response to the second digital pulse 942, the second exponential decay circuit 935 may generate a second exponentially decaying response voltage that gradually decays over a period of time. The second transconductor 936 may generate a second current based on the second exponentially decaying response voltage. When another digital pulse is received at the first terminal 102, the second switch 937 may connect the generated current to the capacitor 124, thereby changing a voltage of the capacitor and updating the weight of the synapse-type memory controlled circuit 950. In an embodiment, the second transconductor 937 generates a negative current that decreases a voltage across the capacitor 124.

A benefit of the embodiment of FIGS. 9A and 9B, is that STDP weight updates may be performed in response to digital pulses as opposed to systems that do not include the exponential decay circuits 932, 935. Hence, the synapse-type memory circuits 900, 950 may be incorporated into digital integrated circuits. Other advantages and benefits of the circuits 900 and 950 will be apparent to persons of ordinary skill in the related art having the benefit of this disclosure.

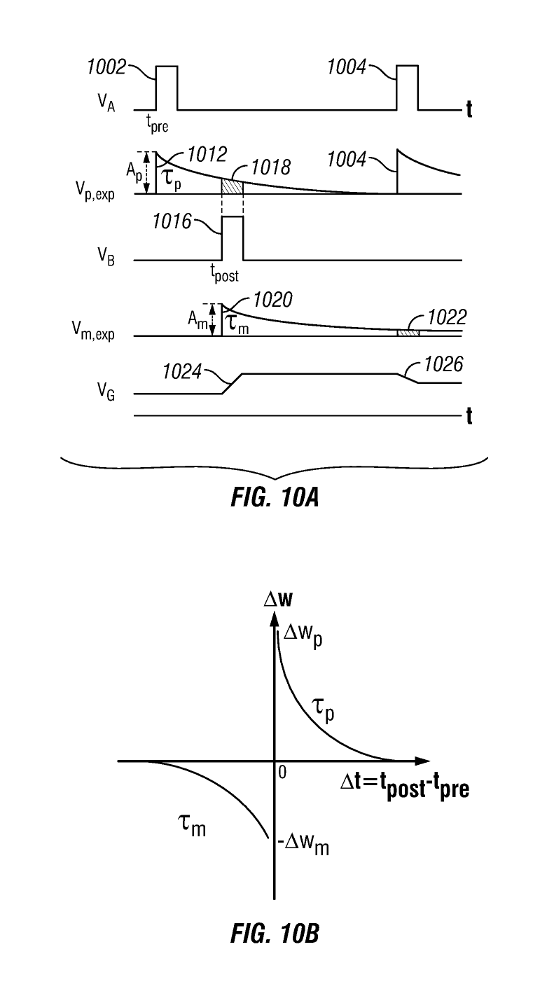

Referring to FIG. 10A, characteristic timing and waveforms of an embodiment of a synapse-type memory controlled circuit using digital spikes, as described herein, are depicted. The characteristic timing and waveforms may correspond to the embodiments of FIGS. 9A and 9B. As depicted in FIG. 10A, a first waveform may correspond to a voltage V_{A} at a first terminal (e.g., the terminal 102). A second waveform may correspond to a voltage Vp,exp corresponding to an exponentially decaying voltage generated by a first exponential decay circuit (e.g., the first exponential decay circuit 932). A third waveform may correspond to a voltage V_{B} at a second terminal (e.g., the second terminal 104). A fourth waveform may correspond to a voltage Vm,exp corresponding to an exponentially decaying voltage generated by a second exponential decay circuit (e.g., the second exponential decay circuit 935). A fifth waveform V_{G} may correspond to a charge held by a capacitor (e.g., the capacitor 124) and applied to a controller (e.g., a gate) of the configurable circuit element 106.

The first waveform may include a voltage pulse 1002 (corresponding to a pre-synaptic pulse) at a time tpre. In response to the voltage pulse 1002, the second waveform may include a voltage spike 1012 followed by an exponentially decaying voltage response with an amplitude of Ap and a time constant τp. The exponentially decaying spike may be sampled (e.g., by actuating the switch 934) during a voltage pulse 1016 of the third waveform. In response to the sampling, a voltage increase 1024 may occur at the fifth waveform. For example, the exponentially decaying voltage response may be converted to a positive current by a transconductor (e.g., the transconductor 933) and integrated onto a capacitor (e.g., the capacitor 124) via a switch (e.g. the switch 934). The voltage increase 1024 may be proportional to the voltage level Vp,exp integrated over the duration of the voltage pulse 1002 (e.g., the area 1018 under the curve Vp,exp).

In a similar manner, the voltage pulse 1016 may cause a voltage spike 1020 followed by an exponentially decaying voltage response in the fourth waveform with an amplitude Am and a time constant τp. The exponentially decaying voltage response may be sampled (e.g., by actuating the switch 937) during a voltage pulse 1004 in the first waveform. In response to the sampling, a voltage decrease 1026 may occur at the fifth waveform. For example, the exponentially decaying voltage response may be converted to a negative current by a transconductor (e.g., the transconductor 935) and integrated onto the capacitor (e.g., the capacitor 124) via a switch (e.g., the switch 937). The voltage decrease 1026 may be proportional to the voltage level Vm,exp integrated over the duration of the voltage pulse 1004 (e.g., the area 1022 under the curve Vm,exp). Thus, the weight corresponding to the synapse-type memory controlled circuit is updated by the relative timing of pre and post digital pulses. Further, in response to the pulse 1004, the second waveform may include a second voltage spike 1014 followed by a second exponentially decaying voltage response. Hence, the operations described herein may be repeated as additional voltage pulses are received at terminals of a synapse-type memory controlled circuit.

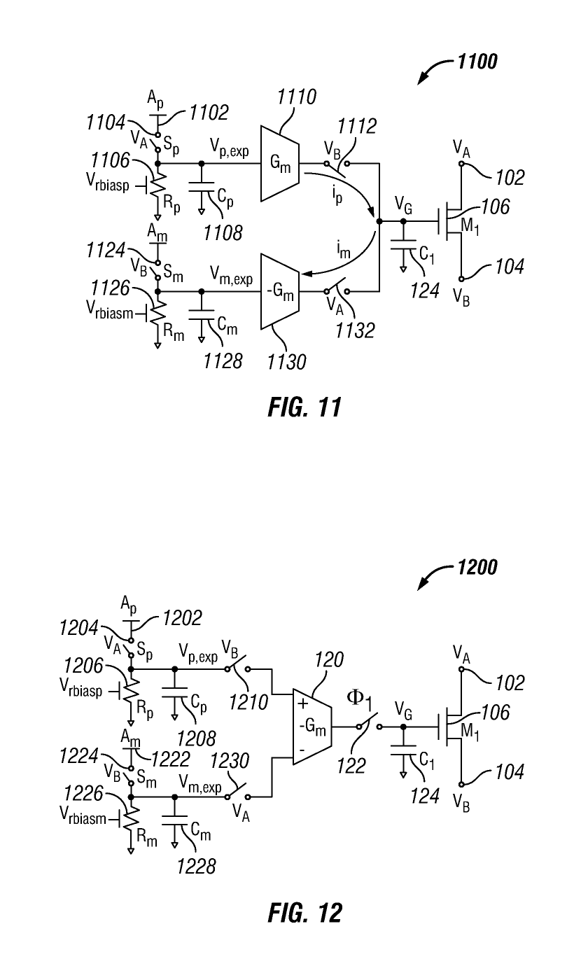

Referring to FIG. 10B, an STDP learning function exhibited by the embodiment of FIG. 11A of a synapse-type memory controlled circuit using digital spikes is depicted. The sampling of exponential decay implements an exponential STDP learning function to enable fast convergence of spiking neural network learning algorithms. Further, the synaptic potentiation may be given by:

$$Δ {w}_{p} \approx \frac{{G}_{m}}{{C}_{1}} {A}_{p} {T}_{pulse}$$

Where Gm is the transconductance of the transconductor 933, C1 is the capacitance of the capacitor 124, Ap is the amplitude of the decaying voltage spike 1012 and Tpulse is the width of the pulse 1002. The synaptic depression may be given by:

$$Δ {w}_{m} \approx \frac{{G}_{m}}{{C}_{1}} {A}_{m} {T}_{pulse}$$

Where Gm is the transconductance of the transconductor 936, C1 is the capacitance of the capacitor 124, Am is the amplitude of the decaying voltage spike 1020 and Tpulse is the width of the pulse 1016.

Referring to FIG. 11, an embodiment of a synapse-type memory controlled circuit with an exponential decay circuit is depicted and generally designated 1100. The synapse-type memory controlled circuit 1100 may correspond to the synapse-type memory controlled circuit 9B. For example, the circuit 1100 may include terminals 102, 104, a configurable circuit element 106, a capacitor 124, a first switch 1112, a second switch 1132, a first transconductor 1110, and a second transconductor 1130. The first switch 1112 may correspond to the switch 934 and the second switch 1132 may correspond to the switch 937. Also, the first transconductor 1110 may correspond to the first transconductor 933 and the second transconductor 1130 may correspond to the second transconductor 936.

The circuit 1100 may further include a first voltage source 1102, third switch 1104, a first resistor 1106, and a capacitor 1108. The first voltage source 1102, the third switch 1104, the first resistor 1106, and the capacitor 1108 may correspond to the first exponential decay circuit 932. The circuit 1100 may further include a second voltage source 1122, a fourth switch 1124, a second resistor 1126, and a capacitor 1128. The fourth switch 1124, the second resistor 1126, and the capacitor 1128 may correspond to the second exponential decay circuit 935. Hence, the exponential decaying responses may be implemented using capacitor charge and discharge circuits.

The first voltage source 1102 may correspond to a voltage level of a peak spike level. For example, referring to FIG. 10A, the peak spike voltage level may correspond to the voltage Aₚ at time tpre. Likewise, the second voltage source 1122 may correspond to a second peak spike level such as the voltage A_{B} at time tpost.

The third switch 1104 may be controlled by a voltage at the first terminal 102. For example, a controller of the third switch 1104 may be coupled to the first terminal 102. The third switch 1104 may enable voltage at the capacitor 1108 to charge to the peak spike level when activated. To illustrate, when activated, the third switch 1104 may couple the capacitor 1108 to the first voltage source 1102, thereby charging the capacitor 1108. When the third switch 1104 is disabled or deactivated, the voltage at the capacitor 1108 may dissipate through the resistor 1106. Similarly, the fourth switch 1124 may be controlled by a voltage at the second terminal 104. The fourth switch 1124 may enable voltage at the capacitor 1128 to charge to the second peak spike level when activated and may enable the capacitor 1128 to discharge through the second resistor 1126 when deactivated.

In an embodiment, the first and second resistors 1106, 1126 include transistors coupled with biasing circuits. The transistors may be biased to function in the triode region using voltage references Vrbiasp and Vrbiasm. Because the transistors are biased to place them in the triode region, the biasing circuit may causes the transistors to generate a resistance, thereby forming a first resistor 1106 and a second resistor 1126.

During operation, the terminal 102 may receive a first digital pulse (e.g., a pre-synaptic pulse). In response to the first digital pulse, the third switch 1104 may activate, causing the capacitor 1108 to charge to a voltage level corresponding to the voltage Ap. When the first digital pulse terminates, the capacitor 1108 may discharge through the resistor 1106 with a time constant τp=Rp Cp, thereby generating a first exponentially decaying voltage Vp,exp. The exponentially decaying voltage Vp,exp may be converted to an exponentially decaying current proportional to the exponentially decaying voltage Vp,exp at the transconductor 1110. Thereafter, the terminal 104 may receive a second digital pulse (e.g., a post-synaptic pulse). In response to the second digital pulse, the first switch 1112 may be activated, causing a connection between the transconductor 1110 and the capacitor 124 to be established, thereby altering a charge of the capacitor 124. For example, if the transconductor 1110 generates a positive current, a voltage level of the capacitor 124 may be increased. If the transconductor 1110 generates a negative current, then a voltage level of the capacitor 124 may be decreased. When the second digital pulse terminates, the first switch 1112 may be deactivated.

Further in response to the second digital pulse, the third switch 1124 may be activated, causing the capacitor 1128 to charge to a voltage level corresponding to the voltage A_{M}. When the second digital pulse terminates, the capacitor 1128 may discharge through the resistor 1126 with a time constant τ=Rm Cm, thereby generating a second exponentially decaying voltage Vm,exp. The second exponentially decaying voltage Vm,exp may be converted to a second exponentially decaying current proportional to the second exponentially decaying voltage Vm,exp at the second transconductor 1130. Thereafter, the terminal 102 may receive a third digital pulse. In response to the third digital pulse, the second switch 1132 may be activated, causing a connection between the transconductor 1130 and the capacitor 124 to be established, thereby altering a charge of the capacitor 124. For example, if the transconductor 1130 generates a negative current, a voltage level of the capacitor 124 may be decreased. If the transconductor 1130 generates a positive current, then a voltage level of the capacitor 124 may be increased. When the third digital pulse terminates, the second switch 1132 may be deactivated. Thus, a value of a dynamic analog memory (e.g., the capacitor 124) may be modified. Because the modification of the value of the voltage at the capacitor 124 is based on an exponentially decaying voltage, a difference between an original value of the capacitor 124 and the modified value may be based on a duration between a first time of the first digital pulse and a second time of the second digital pulse or based on a duration between the second time of the second digital pulse and a third time of the third digital pulse.

Referring to FIG. 12, an embodiment of a synapse-type memory controlled circuit with an exponential decay circuit is depicted and general designated 1200. The circuit 1200 may include terminals 102, 104, a configurable circuit element 106, a capacitor 124, a first switch 1210, a second switch 1230, a first voltage source 1202, a third switch 1204, a first resistor 1206, a capacitor 1208, a second voltage source 1222, a fourth switch 1224, a second resistor 1226, and a capacitor 1228. The embodiment of FIG. 12 may further include a transconductor 120 and a fifth switch 122.

An input of the first switch 1210 may be connected to the resistor 1206 and the capacitor 1208. An output of the first switch 1210 may be coupled to a first input of the transconductor 120. When activated, the first switch may connect the resistor 1206 and the capacitor 1208 to the transconductor 120. Likewise, an input of the second switch 1230 may be connected to an output of the resistor 1226 and the capacitor 1228. An output of the second switch 1230 may be connected to a second input of the transconductor 120. When activated, the second switch 1230 may connect the resistor 1226 and the capacitor 1228 to the transconductor 120. An output of the transconductor 120 may be coupled to the fifth switch 122. The fifth switch 122 may be controlled by a strobe signal Φ1.

Hence, FIG. 12 depicts an embodiment of a STDP synapse-type memory controlled circuit where two transconductors (e.g., the transconductors 1110, 1130 of FIG. 11) are merged into the transconductor 120. The transconductor 120 may sample the exponentially decaying response voltage Vp,exp when the second voltage pulse (e.g., a post-synaptic pulse V_{B}) is present at the terminal 104. Similarly, the exponentially decaying response Vm,exp may be sampled when the first voltage pulse (e.g., a pre-synaptic pulse V_{A}) is present at the terminal 102. An output current of the transconductor 120 may be integrated into the capacitor 124 in response to the strobe signal Φ1. In an embodiment, the strobe signal Φ1 is configured to activate the fifth switch 122 when either the first or second digital pulse are present (e.g., Φ1=(V_{A} OR V_{B})). In an alternative embodiment, the STDP synapse may not include the fifth switch 122 and alternative means may be used to integrate the current onto the capacitor 124.

The STDP synapse-type memory controlled circuits disclosed thus far may realize short-term potentiation (e.g., an increase in weight) and depression (e.g., a decrease in weight) where the weights are stored in a capacitive memory that may be subject to leaks. The duration of storage at the dynamic analog memory may depend on the size of the capacitor and leakage associated with the configurable circuit element (e.g., the transistor), and may range from a few seconds to minutes. In some machine learning applications it may be desirable to hold the learned weights for a longer period of time. This can be realized by employing bi-stability in synapses where after short-term STDP learning, the weight is quantized to either a high or low binary state.

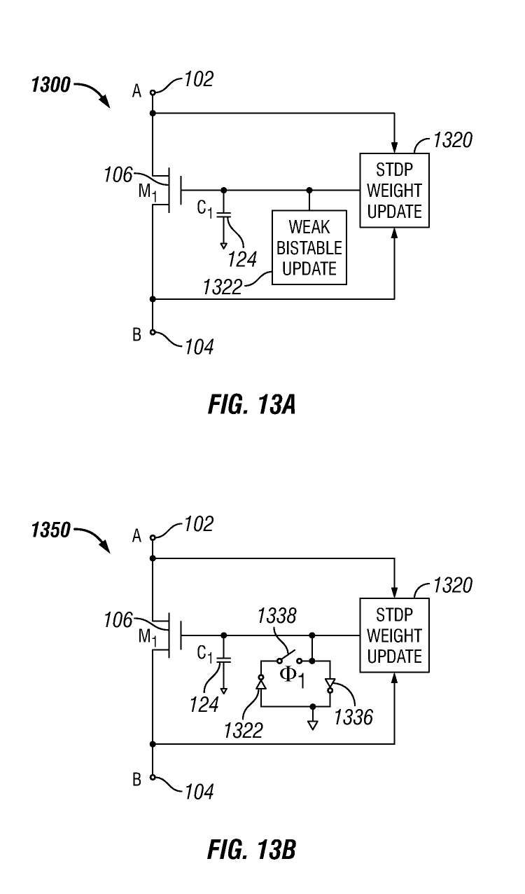

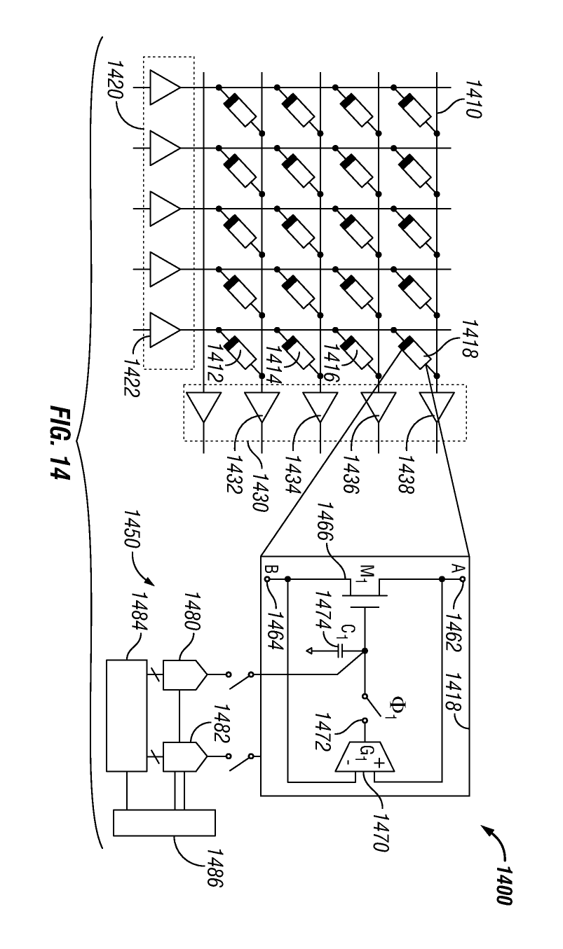

Referring to FIGS. 13A and 13B, embodiments of bi-stable synapse-type memory controlled circuits are depicted. FIG. 13A depicts an embodiment of a bi-stable synapse-type memory controlled circuit 1300 as including terminals 102, 104, a configurable circuit element 106, a capacitor 124, and an STDP weight update circuit 1320. The circuit 1300 also includes a bi-stable memory element 1322 coupled to the capacitor 124.

The bi-stable memory element 1322 may include a weak bi-stable latch. For example, the bi-stable latch may be designed for large regeneration time-constants such that it doesn't interfere in the short-term STDP learning. Between digital or analog pulses (e.g., STDP pulses) the bi-stable memory element 1322 may steer the state of the synapse-type memory controlled circuit to either increase a voltage (e.g., a high conductance state) or decrease the voltage (e.g., a low conductance state).

The bi-stable memory element 1322 may be configured to stabilize a state of the capacitor 124 when activated. For example, the bi-stable memory element 1322 may hold a particular voltage (or draw the particular voltage a high or low value) at the capacitor 124 when activated. When deactivated, the bi-stable memory element 1322 may enable the capacitor 124 to discharge.

FIG. 13B, depicts an embodiment of a bi-stable synapse-type memory controlled circuit 1350 where a first inverter 1332 and a second inverter 1336 are cross-coupled as a binary latch. The inverters 1332, 1336 may include large time-constants resulting in delay times that may prevent the inverters 1332, 1336 from interfering with short term STDP learning (e.g., updating the voltage at the capacitor 124 based on STDP pulses). The large time-constants or inverter delay can be realized by sizing transistors of the inverters 1332, 1336 with large lengths and small widths, and/or starving the current available in the inverters. In an embodiment, a switch 1338 may deactivate the bi-stable memory element 1322 when either pre- or post-synaptic pulses are applied. For example, the bi-stable memory element 1322 may be deactivated in response to a strobe Φ1. The strobe may be set to a logical high in response to a pulse (e.g., V_{A} or V_{B}).

Referring to FIG. 14, an embodiment of a system 1400 of synapse-type memory controlled circuits with a store and refresh scheme using an ADC/DAC combination is depicted. The system 1400 includes a cross-point array 1410, an array of input neuron devices 1420, an array of output neuron devices 1430, and a store and refresh scheme 1450.

The cross-point array 1410 may include a plurality of synapse-type memory controlled circuits organized in a cross-point configuration (using rows and columns) to form a dense neural network (ANN or SNN) layer or a machine learning data structure. Each synapse-type memory controlled circuit of cross-point array 1410 may correspond to a synapse-type memory controlled circuit such as the synapse-type memory controlled circuit 100 of FIGS. 1A and 1B, the synapse-type memory controlled circuit 400 of FIG. 4, the synapse-type memory controlled circuit 500 of FIG. 5A, the synapse-type memory controlled circuit 550 of FIG. 5B, the synapse-type memory controlled circuit 900 of FIG. 9A, the synapse-type memory controlled circuit 950 of FIG. 9B, the synapse-type memory controlled circuit 1100 of FIG. 11, the synapse-type memory controlled circuit 1200 of FIG. 12, the synapse-type memory controlled circuit 1300 of FIG. 13A, and/or the synapse-type memory controlled circuit 1350 of FIG. 13B. As a non-limiting example, each synapse-type memory controlled circuit may include a first input 1462, a second input 1464, a configurable circuit element 1466, a transconductor 1470, a switch 1472, and a capacitor 1474. The plurality of synapse-type memory controlled circuits of the cross-point array 1410 may connect the array of input neuron devices 1420 to the array of output neuron devices 1430.

To illustrate, the array of input neuron devices 1420 may include a first representative input neuron device 1422 and the array of output neuron devices may include a first representative output neuron device 1432, a second representative output neuron device 1434, a third representative output neuron device 1436, and a fourth representative output neuron device 1438. Further, the cross-point array 1410 may include a first representative synapse-type memory controlled circuit 1412, a second representative synapse-type memory controlled circuit 1414, a third representative synapse-type memory controlled circuit 1416, and a fourth representative synapse-type memory controlled circuit 1418. The first representative input neuron device 1422 may be connected to each of the representative output neuron devices 1432-1438 via a corresponding synapse-type memory controlled circuit of the representative synapse-type memory controlled circuits 1412-1418. The number and/or configuration of the input neuron devices, output neuron devices, and synapse-type memory controlled circuits is for illustrative purposes only and may be varied within the scope of the present disclosure as would be appreciated by one of ordinary skill in the art having the benefit of this disclosure.

The store and refresh scheme 1450 may include an analog-to-digital converter (ADC) 1480, a digital-to-analog converter (DAC) 1482, a memory array 1484, and a controller 1486. Each synapse-type memory controlled circuit of the cross-point array 1410 may be coupled to the store and refresh scheme 1450. For example, the ADC 1480 and the DAC 1482 may be coupled to the capacitor 1474 and may enable reading from and writing to the capacitor 1474. The memory array 1484 may include a long-term memory usable to store states associated with each of the synapse-type memory controlled circuits of the cross-point array 1410. The controller 1486 may be configured to control the read and write processes of the ADC 1480 and the DAC 1482.

During operation, a charge at the capacitor 1474, if not continually updated, may leak away due to sub-threshold leakage at the switch 1472 as it is controlled by a strobe Φ1. In order to hold a value (or state) of the synapse-type memory controlled circuit, the value may be periodically read via the ADC 1480 and stored at the memory array 1484. When needed, the value may be recalled from the memory array 1484 and stored at the capacitor 1474 via the DAC 1482.

The system 1400 may operate at very high speeds (up to several GHz), which is beneficial for applications involving big data analytics. Since the system 1400 may be designed using CMOS technology, complicated fabrication steps are not needed to design large neural inspired computing chips. Hence, the system 1400 enables prototype applications targeted for conceptual memristor devices and/or elements. The system 1400 may also synergistically work with memristor devices for fast data processing and non-volatile storage of learned weights in a non-volatile device such as a conducting bridge type memristor, ReRAM, flash memory, and/or phase change memory.

Although, FIG. 14 depicts the cross-point array 1410 as including 20 synapse-type memory controlled circuits, in other embodiments, the cross-point array 1410 may include more or fewer than 20 synapse-type memory controlled circuits. Further, although FIG. 14 depicts the array of input neuron devices 1420 as including 5 input neuron devices, the array of input neuron devices 1420 may include more or fewer than five input neuron devices. Also, although FIG. 14 depicts the array of output neuron devices 1430 as including 5 output neuron devices, the array of output neuron devices 1430 may include more or fewer than five output neuron devices. It should be generally understood that the system depicted in FIG. 14 is for purposes of example only and that in other embodiments, the system may include many more input neuron device, output neuron devices, and synapse-type memory controlled circuits than depicted in FIG. 14.

Although FIG. 14 depicts each synapse-type memory controlled circuit as including the transconductor 1470 and the switch 1472, in one or more other embodiments the synapse-type memory controlled circuits may correspond to embodiments of the synapse-type memory controlled circuits that do not include the transconductor 1470, and the switch 1472 as described with reference to FIGS. 9A-13B. Further, in an embodiment, each synapse-type memory controlled circuit is configured to respond to analog STDP pulses as described herein. Alternatively, each synapse-type memory controlled circuit may be configured to respond to digital STDP pulses as described herein. To illustrate, one or more of the embodiments of synapse-type memory controlled circuits (such as the circuit 900) may be coupled to one or more of the input neuron devices 1420 and to one or more of the output neuron devices 1430. The synapse-type memory controlled circuit 900 may be configured to receive a first digital pulse from one of the input neuron devices 1420 and to pass the first digital pulse to one of the output neuron devices 1430. The synapse-type memory controlled circuit 900 may also receive a second digital pulse from one of the output neuron devices 1430 and pass the second digital pulse to one of the input neuron devices 1420. The synapse-type memory controlled circuit 900 may further change a value of the capacitor 124 based on the first digital pulse and the second digital pulse as described herein. Hence, either an analog synapse-type memory controlled circuit or a digital synapse-type memory controlled circuit may be used in conjunction with the cross-point array 1410.

Although various embodiments have been shown and described, the present disclosure is not so limited and will be understood to include all such modifications and variations, both structural and operational, as would be apparent to one skilled in the art.

What is claimed is:

1. A memory controlled circuit comprising:
a configurable circuit element electrically coupled to a first terminal and to a second terminal;
a transconductor, wherein a first input of the transconductor is electrically coupled to the first terminal and a second input of the transconductor is electrically coupled to the second terminal;
a switch coupled to an output of the transconductor; and
a dynamic analog memory electrically coupled to the configurable circuit element and to the switch.

2. The memory controlled circuit of claim 1, wherein the configurable circuit comprises a transistor configured to operate in a linear region mode or a near-linear region mode.

3. The memory controlled circuit of claim 2, wherein the transistor is a zero threshold voltage transistor.

4. The memory controlled circuit of claim 2, wherein the transistor is an N-channel field effect transistor (FET), a P-channel FET, an NPN bipolar junction transistor (BJT), a PNP BJT, or a junction gate field-effect transistor (JFET).

5. The memory controlled circuit of claim 1, wherein the configurable circuit comprises a variable capacitor.

6. The memory controlled circuit of claim 5, wherein the variable capacitor comprises a three-terminal varactor.

7. The memory controlled circuit of claim 1, wherein the dynamic analog memory comprises a capacitor electrically coupled to a control input of the configurable circuit element and electrically coupled to a common voltage.

8. The memory controlled circuit of claim 7, wherein the capacitor has a capacitance of between about 100 femtofarads and five picofarads.

9. The memory controlled circuit of claim 1, further comprising a bi-stable latch coupled to the configurable circuit element.

10. The memory controlled circuit of claim 1, further comprising a strobe signal source coupled to the switch.

11. The memory controlled circuit of claim 10, wherein the strobe signal source comprises a system clock.

12. The memory controlled circuit of claim 10, wherein the strobe signal source comprises an event detector circuit, wherein a first input of the event detector circuit is electrically coupled to the first terminal and a second input of the event detector circuit is electrically coupled to the second terminal, and wherein an output of event detector circuit is electrically coupled to the switch.

13. The memory controlled circuit of claim 12, wherein the event detector circuit comprises:
an absolute difference circuit configured to generate a signal indicating a magnitude of a voltage difference between the first terminal and the second terminal; and
an asynchronous comparator configured to set a strobe signal to a logical high in response to the magnitude of the voltage difference exceeding a threshold.

14. The memory controlled circuit of claim 12, wherein the event detector circuit comprises:
a first asynchronous comparator configured to set a strobe signal to a logical high in response to a voltage difference between the first terminal and the second terminal exceeding a first threshold; and
a second asynchronous comparator configured to set the strobe signal to a logical high in response to the voltage difference between the first terminal and the second terminal being lower than a second threshold.

15. A method of controlling an electrical property of a circuit, the method comprising:
sensing a voltage difference between a first terminal and a second terminal of a memory controlled circuit;
changing a value of a dynamic analog memory based on the voltage difference; and
changing an electrical property of a configurable circuit element positioned between the first terminal and the second terminal based on the value of the dynamic analog memory.

16. The method of claim 15, wherein changing the value of the dynamic analog memory comprises increasing or decreasing the value of the dynamic analog memory based on an integration operation performed on the sensed voltage difference over time.

17. The method of claim 15, wherein changing the electrical property comprises increasing or decreasing a resistance of the configurable circuit element or increasing or decreasing a capacitance of the configurable circuit element.

18. A system of memory controlled circuits comprising:
at least one input neuron device;
at least one output neuron device;
at least one memory controlled circuit, wherein the at least one input neuron device is coupled to the at least one output neuron device via the at least one memory controlled circuit, and wherein the memory controlled circuit comprises:
a configurable circuit element electrically coupled to a first terminal and to a second terminal;
a transconductor, wherein a first input of the transconductor is electrically coupled to the first terminal and a second input of the transconductor is electrically coupled to the second terminal;
a switch coupled to an output of the transconductor; and
a dynamic analog memory electrically coupled to the configurable circuit element and to the switch.

19. The system of claim 18, wherein the at least one memory controlled circuit enables bi-directional communication between the at least one input neuron device and the at least one output neuron device.

20. The system of claim 18, wherein the memory controlled circuit is configured to control an electrical property of the configurable circuit element based on a voltage difference between a first voltage spike generated by the at least one input neuron device at the first terminal and a second voltage spike generated by the at least one output neuron device at the second terminal.

21. The system of claim 20, wherein the first voltage spike is generated in response to the second voltage spike or the second voltage spike is generated in response to the first voltage spike.

22. The system of claim 20, wherein the electrical property of the configurable circuit element is changed when a period of time between the first voltage spike and the second voltage spike is less than a threshold.

23. The system of claim 18, further comprising at least one analog-to-digital converter coupled to the dynamic analog memory, the analog-to-digital converter enabling a controller to perform a read operation corresponding to the dynamic analog memory.

24. The system of claim 18, further comprising at least one digital-to-analog converter coupled to the at least one memory controlled circuit, the digital-to-analog converter enabling a controller to perform a write or refresh operation corresponding to the dynamic analog memory.

25. The system of claim 18, further comprising a memory array configured to store a value corresponding to the dynamic analog memory.

26. The system of claim 18, further comprising:
a plurality of input neuron devices, the plurality of input neuron devices including the at least one input neuron device;
a plurality of output neuron devices, the plurality of output neuron devices including the at least one output neuron device; and
a plurality of memory controlled circuits, each of the plurality of memory controlled circuits including the at least one memory controlled circuit,
wherein each input neuron device of the plurality of input neuron devices is electrically coupled to each output neuron device of the plurality of output neuron devices via memory controlled circuits.

27. The system of claim 26, wherein the plurality of memory controlled circuits are organized in a cross-point array configuration, wherein the cross point array configuration is a dense neural network layer or a machine learning data structure.
